(19) United States
(12) Patent Application Publication
(10) Pub. No.: US 2004/0189333 A1
(43) Pub. Date: Sep. 30, 2004

(54) Carrier for receiving and electrically contacting individually separated dies

(76) Inventors: Stephan Dobritz, Dresden (DE); Peter Weitz, Sauerlach (DE); Harry Hedler, Germering (DE)

Correspondence Address: SLATER & MATSIL, L.L.P., 17950 PRESTON RD, SUITE 1000, DALLAS, TX, 75252-5793, US

(21) Appl. No.: 10/754,172

(22) Filed: Jan. 9, 2004

(30) Foreign Application Priority Data
Jan. 10, 2003 (DE) 103 00 817.9
Aug. 29, 2003 (DE) 103 40 333.7

(51) Int. Cl. G01R 31/02

(52) U.S. Cl. 324/754

(57) ABSTRACT

The present invention relates to a carrier for receiving and electrically contacting individually separated dies (bare chips) for the testing and/or burn-in of the same, the carrier having first contacts arranged in a grid pattern corresponding to the die to be contacted. The preferred embodiment provides a carrier with which individually separated dies can be mechanically and electrically contacted with precision, allowing the functional testing and burn-in to be carried out with existing equipment, and in particular to realize the “known good die concept”. The preferred embodiment is achieved by first contacts of the carrier being provided with elastomer bumps having second contacts on their tips. The second contacts are electrically connected to the first contacts, and the dies are drawn against the elastomer bumps by a predetermined force that is generated by a vacuum.

### TECHNICAL FIELD

The present invention relates to a carrier for receiving and electrically contacting individually separated dies (bare chips) for the testing and/or burn-in of the same.

### BACKGROUND

Dies are usually made to undergo a functional test after the back-end process, e.g., complete mounting on a supporting element (PCB), and this test may be followed by a burn-in. In the more recent development of components with multiple stacked dies, the test and burn-in after complete mounting can in principle be carried out in the same way as in the case of components with only one die. If, however, defective dies have been fitted here, this would have the consequence that the entire component is rejected, since repair is virtually ruled out. This is not acceptable for commercial reasons.

This situation gives rise to the necessity for the dies to be individually tested, and possibly made to undergo a burn-in, before stacking on a PCB.

To achieve this with the lowest possible costs, existing equipment should be used for testing and burn-in purposes. However, the known clamping and fastening devices are unsuitable for the contacting of aluminium contacts (pads).

The main problem is the small distance of the bonding pads from one another (bonding pad pitch). The reason for this is the requirement for particularly precise positioning of the die, which also has to be ensured until its contacting is complete. The fastening of a die on a carrier usually takes place by mechanical contact pressure being applied by means of a suitable cover which presses the die into the carrier with adequate force. When this happens, there is the risk of relative movement between the die and the carrier. This relative movement can only be reliably detected in an electrical test.

### SUMMARY OF THE INVENTION

A preferred embodiment of the present invention provides a carrier with which individually separated dies can be mechanically and electrically contacted with precision in order to allow the functional testing and burn-in to be carried out with existing equipment, in particular to realize the “known good die concept”.

The preferred embodiment is achieved by the first contacts of the carrier being provided with elastomer bumps, which have second contacts on their tips, which contacts are electrically connected to the first contacts. In addition, the dies are drawn against the elastomer bumps by a predetermined force that is generated, e.g., by a vacuum.

Fixing the individual die after its exact positioning in the carrier by the vacuum makes high positioning accuracy possible both during the fastening and also during the holding of the die during transport and measurement. With the fixing of the die by the suction force generated by the vacuum, relative movement between the carrier and the die is avoided. Later movements or vibrations no longer have any influence on the positioning, as long as the forces thereby occurring are smaller than the suction force of the vacuum, which itself can also be controlled.

The possibility of more precise positioning is also accompanied moreover by the effect that pads with still smaller pitches can be contacted in the carrier according to embodiments of the present invention.

By permanent vacuum suction and mechanical pressing contact over the surface area, compensation for possible bowing and differences in height in the contact system can be achieved at the same time.

According to embodiments of the present invention, the die is drawn by the vacuum suction against elastomer bumps which are capable of compensating for differences in height in the contact system and possibly also absorbing to a certain extent transverse stresses that occur, with the result that they are a prerequisite for reliable contacting of all the contacts of the die.

This aim is pursued by further refinements of the carrier according to the invention, which provide that the second contacts at the tip of the elastomer bumps are gold contacts and/or that the electrical connection of the first contacts to the second contacts is established by conductor tracks rising on the elastomer bumps in a spiral or arcuate manner to the tip.

While a particularly good electrical connection to the contacts of the die is realized by the gold contacts as a consequence of the reduction of the contact resistance, a spiral or arcuate conductor track which winds its way as it were on the elastomer bump up to the tip of the latter is capable of compensating for a compression of the elastomer bump, or else small lateral displacements, without tearing.

If such rising conductor tracks additionally have a copper-nickel-gold layer construction, the advantages presented are combined with the known advantages of such a layer construction, which construction realizes a good and reliable contact.

A further improvement of the contact is achieved in another refinement of the invention by a gold-gold contact being realized between the die and the carrier, since the contact resistance can be further reduced in this way. This is achieved by wiring levels (re-distribution layers) which wire the aluminium contacts of the die to gold contacts being arranged on the die, with the result that the gold contacts at the tip of the elastomer bumps are contacted with the gold contacts of the die created by the re-distribution wiring. However, for this it is also required that the re-distribution layers have the good electrical properties of a copper-nickel-gold layer construction.

Furthermore, it is possible by the use of a re-distribution layer to contact pads with very small pitches in the carrier, since these contacts can be drawn apart from one another by means of the re-distribution layer, as long as the size of the die makes this possible.

Since various handling may be required after the initial mechanical and electrical contacting of the die in the course of the functional testing and burn-in, a further refinement of a carrier provides that the die is fixed until final mounting in the carrier and consequently the need for further contactings is avoided.

A refinement of the invention that is particularly advantageous in this sense provides that the fixing of the die takes place by a cover, which compresses the elastomer bumps with a predetermined pressing force after mounting. Since, as described, the exact position of the die in the carrier is retained by the vacuum suction applied to it, the subsequently performed additional fixing by a cover that possibly also carries out relative movements has no influence on the position of the die.

The additional fixing of the die in this way has several advantages. Firstly, a die fixed in this way cannot be inadvertently displaced, and its testing consequently disturbed, since, as described at the beginning, such a known cover exerts a high pressing force on the die and at the same time shields the latter from external mechanical influencing.

Secondly, after this mechanical fixing, it is possible to dispense with the vacuum suction, which is required, for example, for the transport of the carrier.

Thirdly, the initial suction and subsequent mechanical fixing can be used to insert the die into the existing handling device, with the result that the equipment which is already present for the testing of the conventionally mounted die can be used for the testing of the single die. In addition, the well-known, accurate and reliable methods can also be used for the production of the carrier itself.

By using embodiments of the present invention with regard to elastomer bumps and their ability to compensate for slight lateral and normal displacements without tearing of the contact, it is possible to reduce the pressing force which a cover exerts on the elastomer bumps from previously approximately 20 grams to approximately 2 to 8 grams, preferably 5 grams, per elastomer bump. This reduction considerably simplifies the handling during opening and closing of the cover and also reduces the mechanical stress on the die.

In particular, but not necessarily, this reduction of the pressing force makes it possible for the cover to be formed as a spring element, which likewise makes it possible to revert to the tried-and-tested element of a carrier with good handling.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A shows a schematic representation of a carrier according to the present invention in plan view;

FIG. 1B shows a schematic representation of a carrier according to the present invention in side view;

FIG. 1C shows a schematic sectional representation of a carrier according to the present invention, taken in section along the axis A of FIG. 1A;

FIG. 1D shows a schematic sectional representation of a carrier according to the present invention, taken in section along the axis B of FIG. 1A;

FIGS. 1E and 1F show schematic sectional representations of two embodiments of the carrier according to the present invention, taken in section along the axis A of FIG. 1A;

FIG. 1G shows a schematic sectional representation of the embodiment corresponding to FIG. 1F of the carrier according to the present invention, taken in section along the axis B of FIG. 1A;

FIGS. 2A-2D show schematic representations of the plan view, side view and sectional representations corresponding to FIGS. 1A-1D of an embodiment of the carrier according to the present invention;

FIGS. 2E and 2F show a schematic sectional representation of the carrier according to the present invention, taken in section along the axis B of FIG. 2A, with two embodiments of the cover;

FIGS. 3A and 3B show an enlarged detail of the carrier according to the present invention with part of an auxiliary tool for component loading and unloading, i.e., for releasing (taper pin technology) the cover (snap-in mechanism); and

FIG. 4 shows an enlarged, schematically represented detail of the carrier according to the present invention with an elastomer bump.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

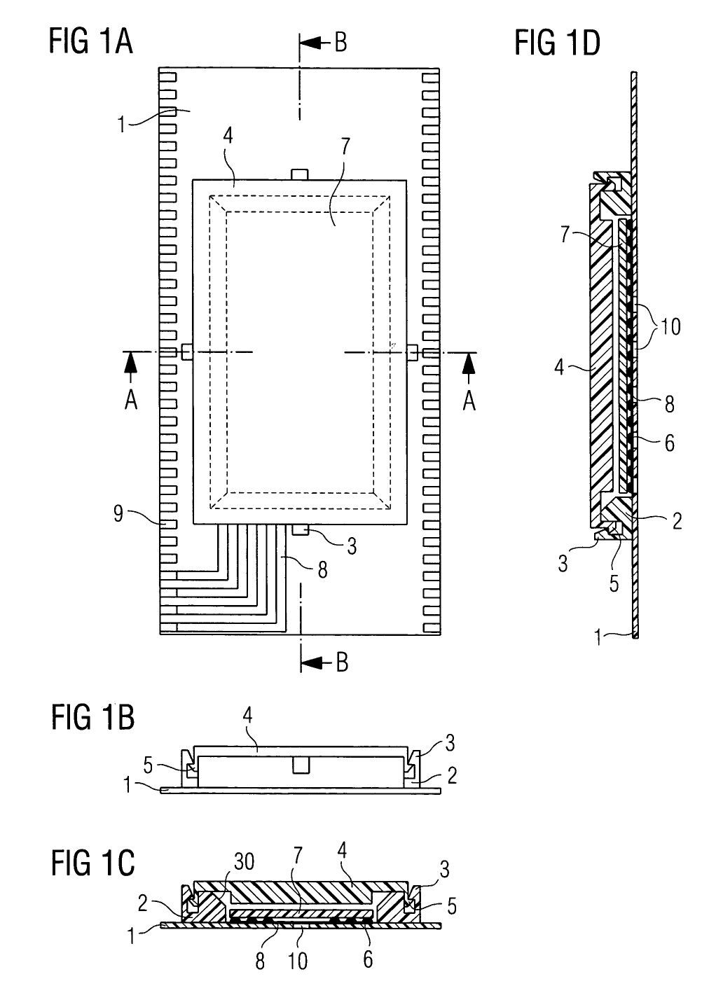

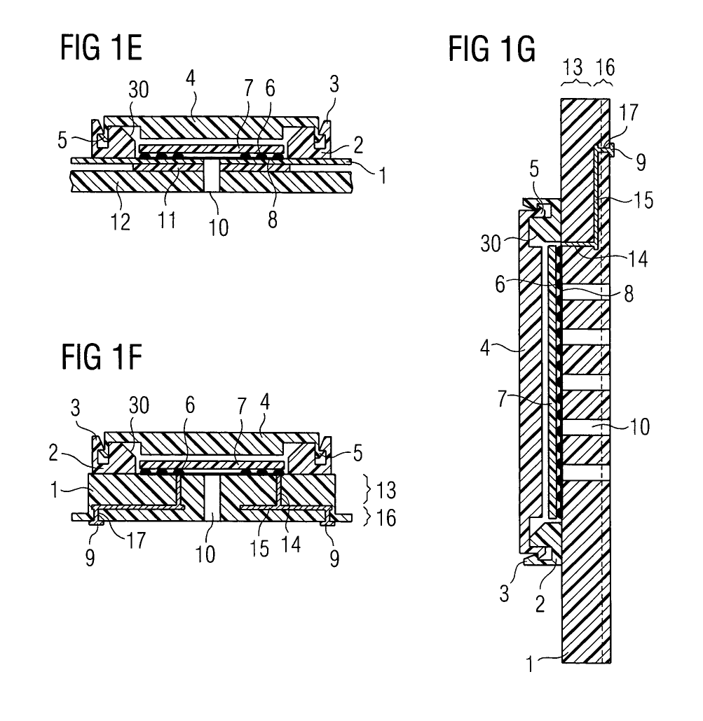

FIGS. 1A-1G show an embodiment of a carrier according to the present invention, substantially comprising a basic support 1, a frame 2 fastened on the latter, having frame clips 3, and a cover 4 resting on the frame 2, having cover clips 5, and elastomer bumps 6. The frame 2 encloses a surface area on the basic support 1 which corresponds to, or is only slightly larger than, the surface area of the individually separated die 7 that is to be received. Within this surface area, the elastomer bumps 6, which serve for the contacting of the die 7, are arranged in a grid-like pattern corresponding to a ball grid array.

The elastomer bumps 6 are electrically connected by means of patterned metallization 8 present on the basic support 1 to contact pads 9, which are located in the edge region of the basic support 1 and serve for the contacting for functional testing and/or burn-in. The die 7 that is to be tested is positioned face-down on the elastomer bumps 6, and consequently within the frame 2.

The positioning of the die 7 requires great accuracy in order to bring the pattern of the bonding pads 28 (see FIG. 4) of the die 7, which may be very closely spaced, into line with the pattern of the elastomer bumps 6. For this purpose, first, the size of the frame 2 is made to match the size of the die 7 and, second, the inner edge of the frame 2, facing the die 7, is bevelled in the direction of the die, with the result that this bevel 30 may serve as a guide during the positioning of the die 7.

For the positioning itself, and similarly for the removal of the die 7, a very sensitive and precise tool is used, as represented in particular by the die bonder. A die bonder (not shown) receives an individual die 7 that is to be tested and guides and positions it within the frame 2 on the elastomer bumps 6.

Directly after the positioning of the die 7, its at least temporary fixing takes place by means of vacuum suction. For this, the basic support 1 has within the frame 2 openings 10, which can be connected to a vacuum system (not shown). As a consequence of the vacuum suction, the die 7 is drawn onto the elastomer bumps 6 and fixed there. Subsequently, the cover 4 is placed with the cover clips 5 onto the frame clips 3 and they are subsequently compressed with force, the clips 3, 5 releasably engaging with respect to one another and arresting the cover 4 on account of their hook form. In this position, the inner side of the cover 4 rests on the rear side of the die 7 and presses it against the elastomer bumps 6. During the mechanical fixing by the cover 4, the vacuum suction can be interrupted. FIGS. 1A to 1D show the various views and sectional representations of this carrier.

The carrier represented in FIG. 1E, with otherwise substantially the same construction, is not contacted by lateral contact pads but by contact pads 9 located on the underside of the basic support 1 with a printed circuit board 11 underneath the basic support 1, by this printed circuit board 11 having contacts (not shown) that correspond to the contact pads 9 and being pressed by an elastomer cushion 12 located thereunder against the basic support 1, and the electrical contact consequently being established.

The vacuum suction likewise takes place in this configuration through openings 10 in the basic support 1, which also continue in the printed circuit board 11 and the elastomer cushion 12.

In FIG. 1F, by virtue of a modified configuration of the basic support 1, the contacting of the carrier is likewise realized by contact pads 9, which are located on the underside of the basic support 1.

In this embodiment, the basic support 1 is formed with two layers. The upper layer has conductive first apertures 14, through which the elastomer bumps 6 are connected to a metallic wiring pattern 15, which is located on the upper side of the lower layer 16, and in turn the first apertures 14 are electrically contacted with conductive second apertures 17 in the lower layer 16.

The second apertures 17 are in turn electrically connected to the contact pads 9 located on the underside of the lower layer 16 of the basic support 1, by the two corresponding to each other. The vacuum suction likewise takes place through openings 10 in the basic support 1, the openings 10 being present right through the lower layer 16 and the upper layer 13.

FIG. 1G presents the embodiment corresponding to FIG. 1F in a further sectional representation, the vertical sectional plane of which lies such that it is turned 90° in relation to the vertical sectional plane of FIG. 1F.

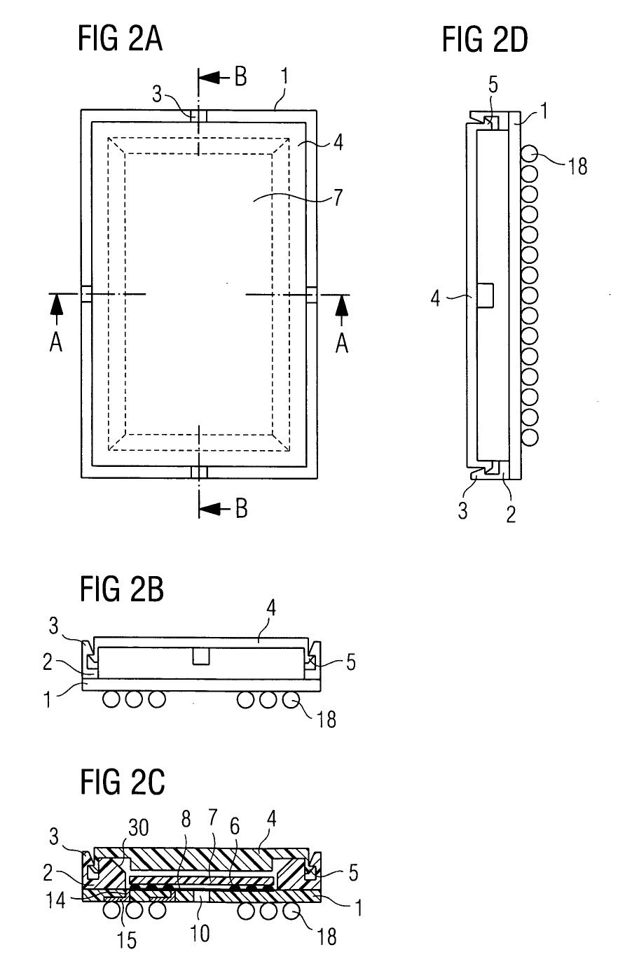

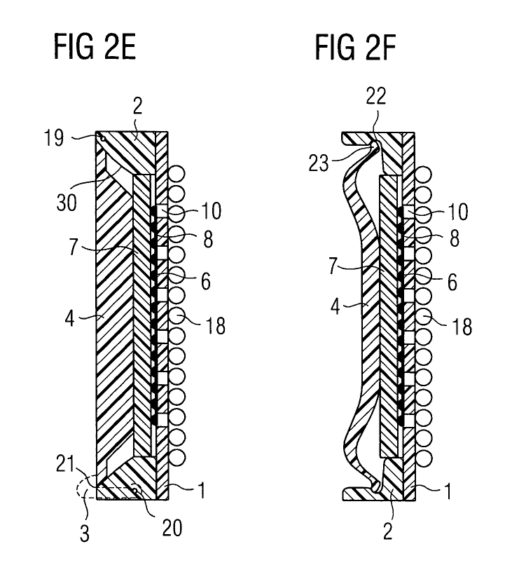

FIGS. 2A-2D present a further embodiment of the carrier according to the present invention, which differs from that represented in FIGS. 1A-1G in that the basic support 1 is merely the size of the frame 2 plus the frame clips 3 and the contacting of the carrier for the functional testing of the die 7 takes place by means of solder balls 18 arranged in a grid-like two-dimensional pattern on the underside of the basic support 1 (like an FBGA).

The electrical connection between the elastomer bumps 6 and the solder balls 18 takes place by conductive, first apertures 14 and a metallic wiring pattern 15 located on the underside of the basic support 1.

In FIGS. 2E and 2F, carriers that can be contacted by means of FBGA-like solder balls 18 are represented. In FIG. 2E, the frame clips 3 and cover clips 5 are replaced on one side face of the frame 2 and of the cover 4 by a first joint 19, with the result that the cover 4 is firmly connected to the frame 2 by the first joint 19 and is mounted pivotably about the axis of this first joint 19, which lies parallel to precisely this side edge of the frame 2.

The other frame clips 3 on the other three sides of the frame 2 are pivotably configured by means of second joints 20, the pivot axes of which lie parallel to the outer frame edge and in a plane which approximately coincides with the side of the cover 4 that faces the die 7.

The cover 4 has an acute-angled edge 21 instead of the cover clips 5, over which the frame clips 3 engage by a pivoting movement about the axis of the second joint 20, in order to arrest the cover 4, and the arrestment can be released again by a pivoting movement of the frame clips 3 in the opposite direction.

FIG. 2F also presents a variant of the arrestment of the cover 4. In this configuration, the frame 2 and the cover 4 have no frame clips 3 and cover clips 5. Instead of these clips 3, 5, the frame 2 exhibits on the inside a peripheral channel 22, into which a peripheral bead 23, forming the outer edge of the cover 4, engages such that it fits.

By virtue of a spring-like form of the cover 4, in the installed state the bead 23 of the cover 4 exerts an outwardly acting force on the frame 2, which brings about the arrestment of the cover 4 and has to be overcome to release the cover 4.

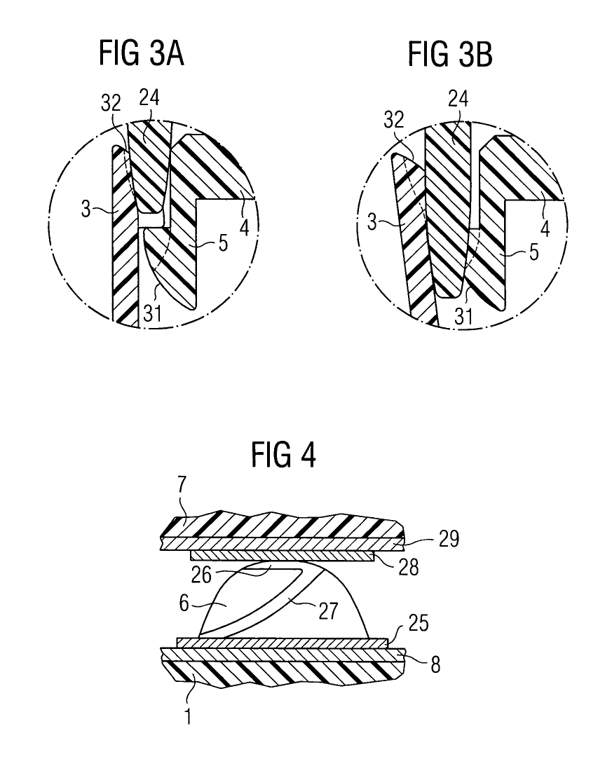

Represented in FIGS. 3A and 3B are two phases of the operation for releasing the frame clips 3 and cover clips 5 (corresponding to FIG. 1) with the aid of an auxiliary tool 24, which has the form of an acute-angled frustrum of a cone with rounded edges. The auxiliary tool 24 is introduced into the intermediate space which exists between the frame clips 3 and the cover 4 and, by pressing of the frustoconical auxiliary tool 24 against the conically formed inner side of the frame clip 3, the latter is moved outwards and in this way comes away from the cover clip 5.

FIG. 4 schematically presents such a detail of the carrier according to the invention in which an elastomer bump 6 can be seen. The basic support 1 comprises a patterned metallization 8, which is in ohmic contact with first contacts 25, which are arranged in a grid-like two-dimensional pattern and in turn bear the elastomer bumps 6.

Each elastomer bump 6 has on its flattened tip a gold contact as a second contact 26, which is electrically connected to the first contact 25 by a conductor track 27 rising on the surface of the elastomer bump 6 in a spiral or arcuate manner and is also electrically connected to a bonding pad 28, which serves for the contacting of the die 7. The die 7 has a re-distribution layer 29 for the electrical connection of the bonding pad 28.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A carrier for receiving and electrically contacting individually separated dies for the testing and/or burn-in of the same, wherein the carrier comprises:
a support structure;
first contacts disposed on the support structure and arranged in a grid pattern corresponding to a die to be contacted;
elastomer bumps provided on the first contacts;
second contacts formed on the elastomer bumps, wherein the second contacts are electrically connected to the first contacts; and
at least one opening in the support structure wherein dies placed on the support structure can be drawn against the elastomer bumps by a force generated by a vacuum and applied through the opening.

2. The carrier of claim 1 wherein the second contacts are comprised of gold.

3. The carrier of claim 1 wherein the electrical connection of the first contacts to the second contacts is established by conductor tracks rising on the elastomer bumps in a spiral or arcuate manner to a tip of the elastomer bump.

4. The carrier of claim 3 wherein the conductor tracks comprise a copper-nickel-gold layer construction.

5. The carrier of claim 1 wherein a gold-gold contact is realized between the die and the carrier by a re-distribution layer arranged on the die.

6. The carrier of claim 1 wherein the re-distribution layer comprises a copper-nickel-gold layer construction.

7. The carrier of claim 1 and further comprising a cover overlying the support structure.

8. The carrier of claim 7 wherein the cover is formed as a spring element.

9. A method of processing a semiconductor die, the method comprising:
providing a semiconductor die, the die including contacts formed in a pattern;
providing a carrier, the carrier comprising first contacts disposed over a surface of a support structure, elastomer bumps provided on the first contacts, and second contacts formed on the elastomer bumps, wherein the second contacts are arranged in a pattern corresponding to the pattern on the die, the second contacts being electrically coupled to the first contacts;
placing the die on the support structure of the carrier;
securing the contacts of the die against the elastomer bumps by a predetermined force generated by a vacuum; and
evaluating the semiconductor die.

10. The method of claim 9 wherein the die is fixed until the contacts of the die are secured against the elastomer bumps.

11. The method of claim 10 wherein the fixing of the die takes place by a cover, wherein the cover compresses the elastomer bumps with a predetermined pressing force after placing.

12. The method of claim 11 wherein the pressing force is approximately 2 to 8 grams per elastomer bump.

13. The method of claim 11 wherein the cover is formed as a spring element.

14. The method of claim 9 wherein providing a semiconductor die comprises:
fabricating a wafer that includes a plurality of semiconductor dies; and
separating the wafer to provide the semiconductor die.

15. The method of claim 9 wherein evaluating the semiconductor die comprises testing the semiconductor die.

16. The method of claim 9 wherein evaluating the semiconductor die comprises burning-in the semiconductor die.

17. The method of claim 9 wherein the second contacts of the carrier are comprised of gold.

18. The method of claim 9 wherein the electrical connection of the first contacts to the second contacts is established by conductor tracks rising on the elastomer bumps in a spiral or arcuate manner to the tip.

19. The carrier of claim 18 wherein the conductor tracks comprise a copper-nickel-gold layer construction.

20. The carrier of claim 9 wherein a gold-gold contact is realized between the die and the carrier by re-distribution layers being arranged on the die, and wherein the re-distribution layers comprise a copper-nickel-gold layer construction.
